(19) United States
(12) Patent Application Publication
(10) Pub. No.: US 2018/0094781 A1
(43) Pub. Date: Apr. 5, 2018

(54) ILLUMINATION UNIT INCLUDING LEDS

(71) Applicant: OSRAM GmbH, Munich (DE)

(72) Inventor: Philipp Schlosser, Regensburg (DE)

(21) Appl. No.: 15/566,229

(22) PCT Filed: Feb. 17, 2016
(86) PCT No.: PCT/EP2016/053326

§ 371 Date: Oct. 13, 2017

(30) Foreign Application Priority Data
Apr. 15, 2015 (DE) 10 2015 206 801.3

(51) Int. Cl. F21K 9/90; F21V 7/00; H05K 1/02; H05K 1/18

(52) U.S. Cl. CPC F21K 9/90; F21V 7/0008; F21V 3/049; H05K 1/189; H05K 1/028

(57) ABSTRACT

An illumination apparatus for emitting light is provided with a planar substrate, a conductor track structure on the substrate, and LEDs assembled on the substrate and connected to the conductor track structure in an electrically conductive manner. Portions of the substrate are partly separated from the remaining substrate by a separating joint that passes through the substrate in the thickness direction of the latter but is open in the direction of longitudinal extent of the latter, i.e. the portions are still respectively connected to the remaining substrate via a bridge region. The separating joints extends completely within the substrate, in each case at a distance from an edge of the substrate in relation to the surface directions thereof. With at least one of the LEDs respectively being assembled in the portions, the portions is folded out of the remaining substrate and is thus placed at an angle thereto.

### RELATED APPLICATIONS

The present application is a national stage entry according to 35 U.S.C. § 371 of PCT application No.: PCT/EP2016/053326 filed on Feb. 17, 2016, which claims priority from German application No.: 10 2015 206 801.3 filed on Apr. 15, 2015, and is incorporated herein by reference in its entirety.

### TECHNICAL FIELD

The present disclosure relates to an illumination apparatus having a planar substrate and a plurality of LEDs thereon.

### BACKGROUND

The advantages that LED-based light sources have over conventional light sources, for example in relation to the energy efficiency, are known. A challenge may arise in respect of the relative arrangement, i.e., specifically, in respect of the assembly, of the LEDs, for example in respect of producing a desired light distribution in the far field, or else of producing a special illuminance distribution, typically an illuminance distribution that is as homogeneous as possible, on an emission surface.

### SUMMARY

The present disclosure is based on the technical problem of specifying a particularly advantageous illumination apparatus and a method for the production thereof.

According to the present disclosure, this object is achieved by an illumination apparatus for emitting light, including a planar substrate, a conductor track structure on the substrate, a plurality of LEDs that are assembled on the substrate and connected to the conductor track structure in an electrically conductive manner, wherein a plurality of portions of the substrate are partly separated from the remaining substrate by, in each case, a separating joint that passes through the substrate in the thickness direction of the latter but is open in direction of longitudinal extent of the latter, i.e. said portions are still respectively connected to the remaining substrate via a bridge region, said separating joints extending completely within the substrate, in each case at a distance from an edge of the substrate in relation to the surface directions thereof, and wherein at least one of the LEDs is respectively arranged in said portions and said portions further are folded out of the remaining substrate, in each case about the bridge region, and thus are placed at an angle thereto;

and by a method including the steps:
providing the substrate;
introducing the separating joints;
folding the portions out of the remaining substrate.

Preferred embodiments are found in the dependent claims and the entire disclosure, with the illustration not always distinguishing in detail between apparatus, method and use aspects; in any case, the disclosure should be read implicitly in respect of all claims categories.

Thus, the basic concept of the present disclosure consists of providing a planar, i.e. thin, substrate but nevertheless achieving an adaptability of the light output (in respect of the directions) that is at least partly detached from the surface by way of folding out the portions. By way of example, this may reduce the production outlay in comparison with a substrate body that is already three-dimensional per se, for example an injection molded part. By way of example, the substrate can be equipped with the LEDs before folding the portions out, i.e., in principle, in a two-dimensional fashion, which may be easier to integrate into mass production than equipping a three-dimensional object. The “planar” substrate has a significantly larger extent, for example at least 20 times, 50 times, 100 times, 250 times, 500 times or 1000 times larger (with increasing preference along the sequence as specified), in each of its surface directions than in the thickness direction perpendicular thereto. Should the substrate have a varying thickness, a mean value that is formed over the substrate is considered in this case; the thickness is advantageously constant.

The portions are in each case partly separated from the remaining substrate by means of a separating joint. The “remaining substrate” is the substrate without all the portions; i.e. no portions belong thereto. However, this separation is only of a conceptual nature; each of the portions is connected to the remaining substrate via the respective bridge region, which is likewise part of the substrate. At least in relation to the surface directions, advantageously overall, the substrate is a monolithic part per se which, apart from inclusions, for example reflection particles, that are arranged distributed therein in a statistically random manner, is free in the interior thereof from material boundaries between different materials or materials with different production histories. Expressed differently, the portions, the remaining substrate and the bridge regions are made from the same, continuous substrate material.

The portions folded out of the remaining substrate are (only) partly separated therefrom by way of the respective separating joint because the separating joints respectively describe open (not closed) curves in their direction of longitudinal extent; the separating joints are advantageously U-shaped in each case.

In any case, the separating joints are situated completely within the substrate in each case, i.e. they do not reach to an outer edge of the substrate (but are at a distance therefrom precisely in relation to the surface directions of the substrate). Expressed differently, the separating joints extend (in relation to the surface directions) between two endpoints in each case and the two endpoints respectively lie within the planar substrate. By way of example, this may be advantageous to the extent that an edge region of the substrate can remain free from separating joints, which may increase the mechanical stability. By virtue of the portions being placed in the surface, it is also possible to realize very large area substrates with a large number of obliquely placed portions/LEDs on the basis of a single substrate.

The illumination apparatus according to the present disclosure has a “plurality” of LEDs, for example, and with increasing preference along this sequence, at least 5, 10, 20, 30, 40, 50, 60, 70, 80, 90 or 100 LEDs; possible upper limits may (independently thereof) lie at e.g. at most 1000 or 500 LEDs. By way of the illumination apparatus and a corresponding number of LEDs, it is possible, for example, to realize a large area light output, wherein it is possible, for example, to obtain a homogeneous illuminance distribution on the output side using the folded-out portions, as explained in more detail below.

At least one LED and, for example, no more than 5, 4, 3 or 2 LEDs (with increasing preference along the sequence of the citation) should be provided in the portions in each case; it is particularly preferred for exactly one LED to be arranged in each portion. “LED” advantageously means an independently packaged LED chip. By way of example, at least 5 portions (and independently thereof) e.g. no more than 1000 portions may be provided as a “plurality” of portions; the lower and upper limits disclosed above for the number of LEDs in the illumination apparatus may also be preferred in the case of the portions (also independently of how many LEDs are provided in each portion).

Further components may also be arranged on the substrate together with the LEDs, for example driver and/or control electronics, or else series resistors, plugs or further components serving for contacting the LED/the operation of the LED. Naturally, further LEDs also may be provided, in general, on the substrate in addition to the LEDs which are arranged according to the present disclosure in the portions. However, advantageously all LEDs of the illumination apparatus are arranged in folded-out portions which are formed by a separating joint in each case. In general, the portions respectively have e.g. an area of at least 10 mm², 30 mm² or 50 mm² and, independently thereof, an area of, for example, no more than 5000 mm², 3000 mm², 1000 mm² or 500 mm² (in each case with increasing preference along the sequence of the citation).

The portions are folded out of the remaining substrate about the respective bridge region; i.e. they are bent out of the remaining substrate around said bridge region as a type of hinge, for example by, with increasing preference along the sequence, at least 10°, 15°, 20°, 25°, 30°, 35° or 40° and (independently thereof) e.g. by, with increasing preference along the sequence, no more than at most 80°, 70°, 60° or 50° in each case. The three-dimensional arrangement created by the bending out process remains on account of a plastic deformation of the substrate itself and/or a part connected therewith (advantageously the conductor track structure, see below).

Advantageously, the portions are respectively folded out of the remaining substrate about a folding line, i.e. a folding line respectively marks the transition between the portion and the remaining substrate. Then, the respective folding line for each portion advantageously extends as a straight connecting line between the two endpoints of the associated separating joint.

Advantageously, the remaining substrate is plane per se and/or the portions are respectively plane per se; it is particularly preferable for both to apply.

The remaining substrate is considered “plane per se” if a region thereof within which the portions lie is plane. Thus, the remaining substrate may be bent e.g. in an edge portion for assembly purposes. The remaining substrate that is “plane per se” should for example be plane over at least 70%, 80% or 90% by area.

In a preferred configuration, the remaining substrate is at least 30% by area of the substrate, with at least 40%, 50% and 60% being further lower bounds, which are increasingly preferred in the sequence of the citation. On the other hand, the remaining substrate should be no more than 90% or 80% by area for example.

To the extent that reference is made to a “plane” configuration of the remaining substrate/the portions, this means that the side surfaces that are opposite one another in relation to the thickness direction respectively lie in a plane in the corresponding region (the respective portion/the remaining substrate) and these planes are parallel to one another (the planes have a distance from one another that corresponds to the thickness of the substrate). Surface and thickness direction of the substrate are always considered locally; thus, for example, they are also placed obliquely in relation to the remaining substrate, together with a respective portion.

In this respect, a respective portion being folded out or placed “obliquely” in relation to the remaining substrate means, for example, that the thickness direction in the respective portion lies at a tilt with respect to that in the remaining substrate of at least 10°, 15°, 20°, 25°, 30°, 35° or 40°, with increasing preference along this sequence; upper limits that are independent of these lower limits may lie at e.g. at most 80°, 70°, 60° or 50°, with increasing preference along this sequence.

As a consequence of the “oblique” placement of a respective portion relative to the remaining substrate, the main propagation direction of the light emitted by the respective portion may be tilted, for example, by at least 10°, 15°, 20°, 25°, 30°, 35° or 40°, with increasing preference along this sequence, in relation to the thickness direction of the remaining substrate; possible upper limits lie (independently of the lower limits) at e.g. at most 80°, 70°, 60° or 50°, with increasing preference along this sequence. The “main propagation direction” in this case is formed as a mean of all directional vectors along which light is emitted by the LED(s), with each direction vector being weighted by its associated illuminance during this formation of the mean.

Here, the thickness direction of the remaining substrate is initially taken immediately at the separating joint of the respective portion in the remaining substrate for each portion, where necessary as a mean formed along the separating joint. In the preferred case of the remaining substrate that is plane per se, the thickness direction of the plane part thereof is based thereon.

Thus, even if the portions are advantageously plane per se in each case, they also may have a more complex structure in general; for example, they may be subdivided into a plurality of partial surfaces in each case. Then, e.g. closest neighboring partial surfaces can be tilted to one another in each portion but be plane per se in each case. Naturally, e.g. only one partial surface that is plane per se, on which the LED(s) is/are seated, may also be combined with partial surfaces (in each portion) that are not plane per se.

In a preferred configuration, the substrate is provided from a plastics material, for example a polyester material, advantageously polyethylene terephthalate (PET). The substrate advantageously has one layer (that is monolithic in relation to the thickness direction); thus, by way of example, this relates to a single plastics sheet.

In general, the substrate could be provided from e.g. a metal as well, for example aluminum or an aluminum alloy. Then, an insulation layer, for example an imide layer, would be arranged between the substrate and the conductor track structure. Regardless of whether the conductor track structure and the substrate directly adjoin one another (which is preferred) or whether a layer or a layer system is still arranged therebetween, the substrate and the conductor track structure form an integral part; i.e., they cannot be separated from one another in a nondestructive manner (without destroying part of the composite).

In a preferred embodiment, the substrate is arranged on a carrier which has a higher flexural rigidity. By way of example, the flexural rigidity of the carrier should be at least 2 times, 4 times, 6 times, 8 times or 10 times that of the substrate. In principle, provision can also be made of a rigid carrier; equally, preferred upper limits lie at e.g. at most 1000 times, 500 times or 100 times the flexural rigidity of the substrate. The carrier can be provided from e.g. a metal or, advantageously, a plastics material, particularly advantageously PET. The higher flexural rigidity also can be achieved, for example, by a thickness that is greater in comparison with that of the substrate.

Even if, in general, e.g. a lattice also is conceivable as a carrier, a planar carrier that has a continuous (non-interrupted) embodiment in relation to its surface directions, for example a sheet, is preferred. The thickness thereof, which generally is taken as an average perpendicular to the surface directions and advantageously constant, may be e.g. at least 0.5 mm, advantageously at least 1 mm, more advantageously at least 1.5 mm, particularly advantageously at least 2 mm, wherein (independently thereof) possible upper limits lie at e.g. at most 5 mm, 4 mm or 3 mm (with increasing preference along the sequence of the citation). Further, the numerical values cited in respect of the planar extent of the substrate should also be disclosed for the carrier (the extent thereof from outer edge to outer edge). The carrier adjoins in the thickness direction of the remaining substrate; the latter and the carrier extend parallel to one another. By way of example, the carrier should extend along the remaining substrate over at least 60%, 70%, 80% or 90% of the area of the remaining substrate. The carrier is advantageously an overall planar part.

The substrate and the carrier have integral embodiment together; i.e., they are not separable from one another in a nondestructive manner (without destroying one of the two or a layer therebetween). Advantageously, the carrier and the substrate are placed against one another as previously separate parts and connected to one another by means of an integrally bonded joining connection, advantageously an adhesive connection, particularly advantageously a large-area adhesive film. By way of example, the substrate and carrier can also be assembled in a reel-to-reel process.

By folding the portions out of the remaining substrate, the latter is interrupted where the portions are folded out. In the region of these interruptions in the remaining substrate, the carrier can likewise be interrupted (continuously in respect of its thickness direction), either partly or advantageously completely congruent with the interruptions in the remaining substrate. By way of example, this may be of interest in the case of an illumination apparatus which should emit light on both sides of the substrate, i.e., for example, in the case of a luminaire that should illuminate both wall and/or ceiling and also the space in front thereof.

In a preferred embodiment, a planar reflector is provided on the substrate (cf. the disclosure above in respect of the “planar property” of substrate and carrier); the reflector and the substrate have an integral embodiment with one another, i.e. they are not separable from one another in a nondestructive manner (cf. the disclosure above in respect of the carrier). In general, the reflector can also be applied as reflection layer, i.e. as a layer which only arises/arose with the application and, in this respect, was not a separate part previously. However, the reflector and the substrate are advantageously placed against one another as previously separate parts and held against one another using an integrally bonded joining connection, particularly advantageously an adhesive connection, in particular a large-area adhesive film (cf. the disclosure above in respect of carrier and substrate).

The reflector is made from a material with a reflectance of at least 60%, of, with increasing preference along this sequence, at least 65%, 70%, 75%, 80%, 85%, 90%, 95%, 97% or 98%; even if a reflectance that is as high as possible may be preferable, an upper limit may lie at e.g. 99.9% for technical reasons (in each case, a mean is considered that is formed over the visible spectral range from 380 μm to 780 μm). In general, the reflector could also be provided made of a metal; however, a reflector made of a plastics material is preferred and the reflectivity is further advantageously set by inclusions embedded therein, for example embedded gas bubbles or, advantageously, reflection particles, e.g. titanium dioxide particles. The reflector is advantageously a plastics sheet.

In a preferred configuration, carrier and reflector are the same part which, therefore, is distinguished by the flexural rigidity and the reflection properties at the same time. Then, for example, fewer individual parts have to be put together.

Advantageously, the reflector is arranged on a front side of the substrate on which the LEDs of the portions are assembled. The portions can then, more advantageously, be folded out toward the rear side that is opposite to this front side; thus, although the light of the LEDs is emitted at the front side of the substrate, it is then reflected and emitted overall by the illumination apparatus on the rear side of the substrate; cf. FIG. 1 for illustrative purposes. This indirectly emitted light for example already can produce a comparatively homogeneous illuminance distribution on a downstream diffuser which, for example, allows a smaller distance between illumination apparatus and diffuser and hence allows a compact construction (cf. FIG. 4 for illustrative purposes). On the other hand, the scattering coefficient of the diffuser can also be reduced as said diffuser is required to scatter less strongly for the purposes of generating a homogeneous illuminance distribution on its output side if the illuminance is already more homogeneous on its input side. This can increase the efficiency.

In a preferred embodiment, the portions are therefore folded out toward a rear side of the substrate that is opposite to the front side (cf. the definition below). Thus, the portions are folded into a rear space, the rear side of the substrate facing (and the front side facing away from) said rear space.

In a further configuration of the portions that are folded out toward the rear side, the reflector provided at the front side extends over the interruptions in the remaining substrate (see above), said reflector in turn being without interruptions. The light of the LEDs thus impinges on a side of the reflector facing the substrate and said light is output into the aforementioned rear space after the reflection. Using this design, it is possible to maximize the portion of the indirectly emitted light; by way of example, it can lie at e.g. at least 70%, 80% or 90% (with increasing preference along the sequence of the citation), wherein the illumination apparatus particularly advantageously only outputs indirect light, i.e. it can be referred to as “glare free”.

The “front side” is that side of the substrate on which the LEDs of the portions in question are arranged. These portions are equipped on one side in each case, i.e. one side is free from LEDs on each portion; further, the LEDs of the portions are assembled on the same side, which is likewise referred to as front side, of the substrate. In general, LEDs also may be assembled additionally on the rear side of the substrate; however, the rear side of the substrate advantageously is free from LEDs, i.e. the substrate overall is only equipped on one side.

By way of example, this may be advantageous to the extent that a layer system that includes the substrate can already be designed more easily and, as a result thereof, more cost-effectively; for example, conductor tracks also are required on one side of the substrate only. Further, equipping on one side can also be simplified in relation to equipping on both sides. Then, all portions of the illumination apparatus are advantageously folded out toward the same side.

In another preferred embodiment (to the embodiment described previously in the context of indirect light output), the portions are folded out toward the front side of the substrate. Thus, the portions are folded into a front space which is faced by the front side of the substrate. A certain homogenization of the illuminance distribution on the input side of the diffuser can also already be achieved, even if only some of the light impinging thereon is indirect light.

To this end, the portions can precisely be folded out e.g. toward the front side and the reflector can be arranged on said front side. In this case, the light emission overall occurs at the front side of the substrate, i.e. the diffuser faces the front side (which is partly covered by the reflector) of the substrate. Then, a mixture of (reflection free) light that is emitted directly by the LEDs and light that was reflected at the reflector impinges on the diffuser, wherein the ratio may also be set by virtue of how obliquely the portions have been placed (the more oblique, the more light is reflected).

In a preferred embodiment, the substrate has a thickness of at least 150 μm, advantageously at least 200 μm, particularly advantageously at least 250 μm. By way of example, advantageous upper limits can lie at at most 500 μm, advantageously at at most 450 μm, further advantageously at at most 400 μm, particularly advantageously at at most 350 μm, wherein the upper and lower limits expressly also may be of interest independently of one another. By way of example, in the case of the preferred plastics material, e.g. PET, the inventor determined firstly that the substrate has a good basic stability in the aforementioned range and secondly that the portions can be folded out well.

In a preferred embodiment, which may also be of interest independently of providing a specific substrate thickness, the conductor tracks have a thickness of at least 20 μm, advantageously at least 25 μm, further advantageously at least 30 μm, particularly advantageously at least 35 μm. Advantageous upper limits can lie e.g. at at most 100 μm, advantageously at at most 90 μm, further advantageously at at most 80 μm, particularly advantageously at at most 70 μm, wherein the upper and lower limit once again may also be of interest independently of one another.

A copper material is preferred for the conductor track structure. By way of example, the copper can be, or have been, laminated thereon such that, for example, a copper film is connected in an integrally bonded manner to the substrate by way of an adhesive layer. Copper that is deposited on the substrate in electroless fashion in a bath is preferred. Here, for example, a part of the layer (seed layer) can be deposited and structured initially in a first step or else it can be deposited straight away on a mask and the seed layer then is strengthened to form the conductor track structure in a second deposition step. However, a one-step deposition is also possible.

The thickness of the substrate/conductor track structure is taken along the thickness direction(s) of the substrate wherein, should a thickness be uneven over the substrate, a mean that is formed thereover is considered. In each case, a constant thickness is preferred.

The present disclosure also relates to a luminaire including an illumination apparatus as is disclosed presently and a diffuser. Here, the illumination apparatus and the diffuser are arranged relative to one another in such a way that at least some of the light that is emitted by the illumination apparatus impinges on the diffuser, for example at least 30%, advantageously at least 40%, of the light. Since, in general, the illumination apparatus may be designed also to emit light on both sides of the substrate, it is not necessarily necessary for the entire light to be guided by the diffuser; by way of example, a wall/ceiling and, via the diffuser, the space in front thereof can be illuminated at the same time (see above). Provision can also be made of a second diffuser such that, in that case, respectively one diffuser is arranged on both sides of the substrate. In the aforementioned example, the space would be illuminated by the first diffuser and the wall/ceiling would be illuminated by the second diffuser.

However, if the entire light is output on one side of the substrate, a correspondingly larger portion of the light advantageously impinges on the diffuser, for example at least 80% or 90%. However, for technical reasons, upper limits may lie at e.g. 99% or 95%. The diffuser is advantageously embodied as a plane parallel plate, in any case in the region which is passed by the light emitted by the illumination apparatus.

The scattering by the diffuser can for example be set by scattering centers that are embedded in the diffuser material, for example scattering particles, and/or by surface scattering centers on the input and/or output side of the diffuser. The surface scattering centers may be realized, for example, by roughing on the surface or an applied, scattering coat.

As already mentioned at the outset, the present disclosure also relates to a production method. The explanation made above in respect of the illumination apparatus and the luminaire should expressly be disclosed also in this respect.

In a preferred configuration, the separating joints are introduced using a mechanical cutting tool or by laser cutting. A punching tool is preferred as a mechanical cutting tool; thus, the separating joints then are punched which, for example, is also possible in a reel-to-reel process. However, in general, the separating joints can also be e.g. etched; however, in contrast thereto, punching may offer advantages in relation to the throughput and, as a result thereof, in particular in mass production, whereas laser cutting permits a high flexibility.

On the basis of these different examples, it also becomes clear that the separating joints also can have very different widths, depending on their production. The width of a separating joint is respectively taken perpendicular to its direction of longitudinal extent, in a respective surface direction of the substrate, and, in particular, should a width vary over the direction of longitudinal extent, it is taken as a mean formed thereover. Here, the substrate is considered with portions that have not yet been folded out, i.e., in the case of the completed illumination apparatus, a situation as if the portions have not yet been folded out (or imagined to be folded in again).

By way of example, in the case of the separating joint that has been introduced with a cutting tool, said separating joint can also be arbitrarily small; i.e., the portion and the remaining substrate may even adjoin one another along the separating joint. By contrast, there will be a certain minimum width in the case of laser cutting, for example 50 μm, 100 μm or 150 μm. However, a wider separating joint can also be introduced with a cutting tool, for example using two blades that extend parallel to one another, their distance from one another predetermining the width of the separating joint. In general, it is preferable for the width of the separating joint to be no greater than 500 μm, 400 μm, 300 μm or 200 μm.

In a preferred embodiment, the conductor track structure is plastically deformed locally when folding out the portions; i.e. the conductor track structure stabilizes the folded-out position at least in part. Thus, the conductor track structure would have to be plastically deformed again in order to fold the portions back in again. The aforementioned thicknesses were found to be advantageous, particularly in conjunction with this stabilization function. By way of example, the “local” deformation respectively takes place where a respective folding line in the substrate intersects with the conductor track structure.

In view of such a stabilization of the portions, it may also be preferable for provision to be made of a stabilization metalization respectively where the respective folding line extends in addition to the conductor track structure, said stabilization metalization not being connected therewith in an electrically conductive manner but advantageously being applied in the same process as the conductive track structure. Such a stabilization metalization thus not contributing to carrying current can cover the respective folding lines e.g. over the largest possible area and, when folding out the portions, can plastically deform there, as just explained for the conductor track structure.

In a preferred configuration, the LEDs are already assembled on the substrate when folding out the portions; that is to say, the LEDs are assembled first and the portions are subsequently folded out. This can significantly simplify the assembly of the LEDs. Advantageously, the LEDs also are already assembled on the substrate when introducing the separating joints on.

As already explained in detail above, a preferred illumination apparatus has a carrier and/or reflector, the two advantageously being an integrated part. Then, in a preferred configuration, the putting together is effectuated in such a way that, initially, the portions are folded out of the substrate and, subsequently, the substrate and the carrier/reflector are put together. Thus, the portions are already folded out of the substrate when putting together the carrier/reflector with said substrate.

### BRIEF DESCRIPTION OF THE DRAWINGS

Below, the present disclosure will be explained in more detail on the basis of an exemplary embodiment, wherein the individual features within the scope of the independent claims may also be essential to the present disclosure in other combinations and no distinction is continued to be made in detail between the various claim categories.

In the drawings, like reference characters generally refer to the same parts throughout the different views. The drawings are not necessarily to scale, emphasis instead generally being placed upon illustrating the principles of the disclosed embodiments. In the following description, various embodiments described with reference to the following drawings, in which:

FIG. 1 shows a luminaire including an illumination apparatus according to the present disclosure therein;

FIGS. 2A-2F show various steps of the production of an illumination apparatus according to the present disclosure;

FIG. 3 shows an oblique view of an illumination apparatus according to the present disclosure; and

FIG. 4 shows a schematic diagram for elucidating the homogenization of the illuminance distribution that is achievable with an illumination apparatus according to the present disclosure on the diffuser of the luminaire according to FIG. 1.

### DETAILED DESCRIPTION

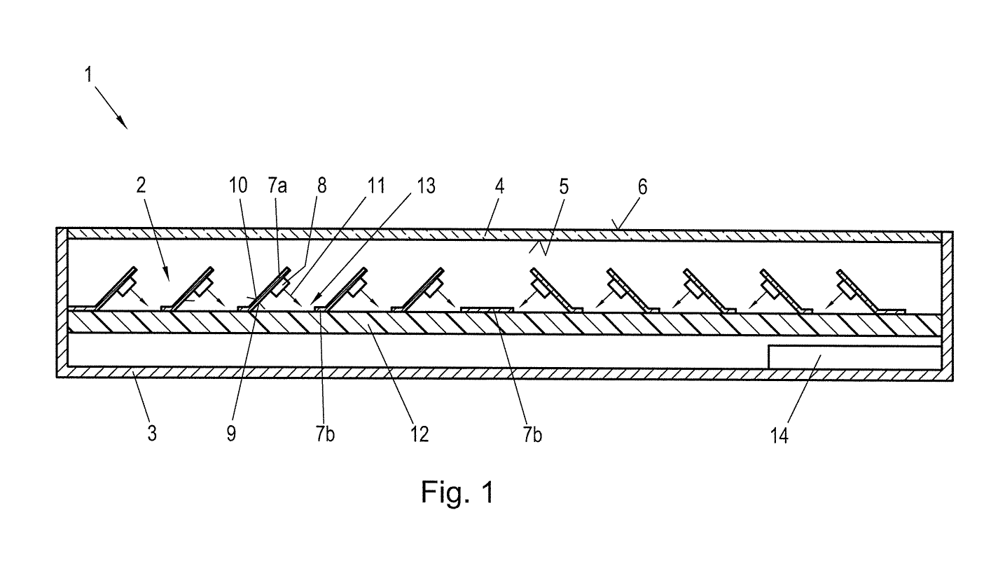

FIG. 1 shows a luminaire 1 including an illumination apparatus 2 according to the present disclosure, the latter being arranged in a casing 3 of the luminaire 1. In the figure, the light emission is effectuated upward and a diffuser 4 of the luminaire 1 is provided downstream of the illumination apparatus 2. The light emitted by the illumination apparatus 2 is incident on an input side 5 of the diffuser 4, scattered at scattering particles (not depicted) that are embedded in the diffuser material and emitted with an accordingly more homogeneous illuminance distribution on an output side 6 of the diffuser 4.

A relatively homogeneous illuminance distribution can already be achieved on the input side 5 of the diffuser 4 using the illumination apparatus 2 according to the present disclosure that is explained in detail below, which is why it is then possible to provide a diffuser with less scattering for the luminaire 1, improving the efficiency. Secondly, it is also possible, for example, to reduce the distance between diffuser and illumination apparatus 2, which may facilitate the construction of particularly flat luminaires 1. The luminaire 1 is advantageously a recessed luminaire.

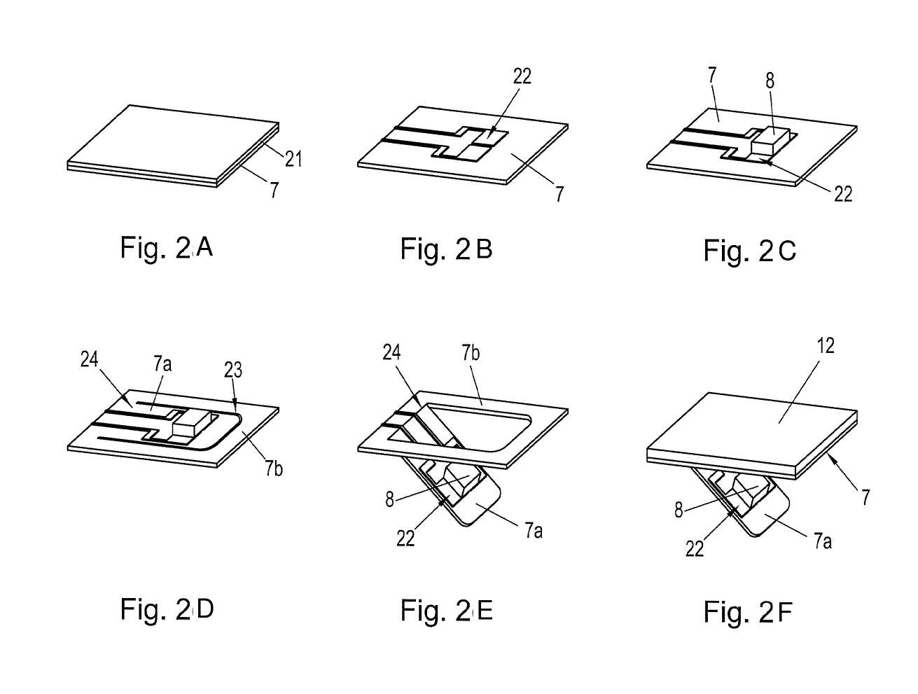

The illumination apparatus 2 according to the present disclosure is constructed from a substrate 7, from which a plurality of portions 7a have been folded out. A plastics sheet made of PET with a thickness of 300 μm is provided as the substrate 7. The portions 7a are partly separated from the remaining substrate 7b via a separating joint in each case; cf., in particular, FIG. 2D for illustrative purposes as well. Respectively one LED 8 is assembled in each of the portions 7a; the LEDs 8 are therefore folded out of the remaining substrate 7b, respectively together with their respective portion 7a, and thus placed obliquely in relation to said remaining substrate.

The LEDs 8 are assembled on a front side 9 of the substrate 7. The portions 7a are respectively folded out toward a rear side 10 that is opposite to this front side 9. The LEDs 8 emit the light in each case approximately according to Lambert's law, wherein a respective main propagation direction 11 that is formed as a mean value for each LED 8 points obliquely downward (approximately at a 45° angle from the perpendicular).

Thus, from the LEDs 8, respectively only a relatively small part of the light reaches the diffuser 4 directly, i.e. without reflection. The greater part of the light is reflected in advance, to be precise at a reflector 12 and also at the substrate 7 itself. The reflector 12 is also a PET plastics sheet which however, with a thickness of 600 μm, is thicker than the substrate 7. On account of the greater thickness, the reflector 12 has a greater flexural rigidity in comparison with the substrate 7. Thus, the reflector 12 simultaneously serves for mechanical stabilization of the substrate 7; i.e., it is also a carrier at the same time.

The remaining substrate 7b is interrupted where the portions 7a are folded out of the latter. The reflector/carrier 12 has a continuous embodiment in the region of these interruptions 13, i.e. it extends over the interruptions 13.

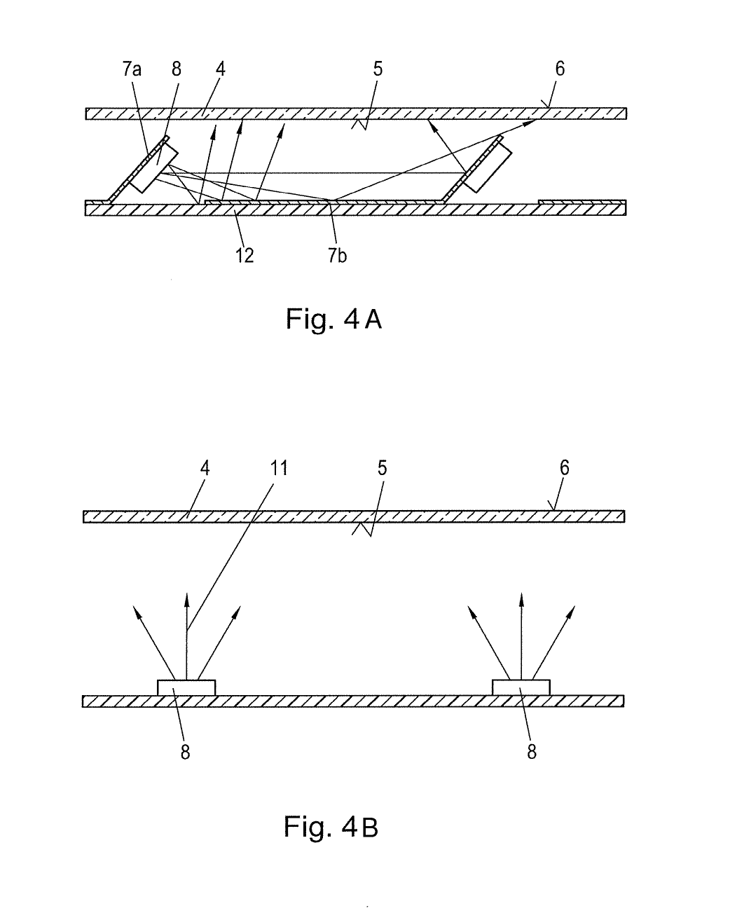

Since the light emitted by the LEDs 8 therefore now reaches the diffuser 4 only partly without reflections and the majority is reflected in advance, a relatively large region of the diffuser 4 is illuminated by each individual one of the LEDs 8. These regions overlap which, as a result, leads to a comparatively more uniform illuminance distribution on the input side 5 of the diffuser 4; in this respect, cf. also FIG. 4 in detail.

For reasons of clarity, FIG. 1 does not depict a conductor track structure that serves for the electrical contacting of the LEDs 8. This conductor track structure is deposited on the front side 9 of the substrate 7 (before the substrate 7 and reflector are put together). Thus, in the completed illumination apparatus 2, said conductor track structure then extends in part between the substrate 7 and reflector 12 and precisely on the side of the portions 7a facing the reflector 12 in the portions 7a.

The luminaire 1 further has driver electronics 14 that are arranged together with the illumination apparatus 2 in the casing 3 and are connected in an electrically conductive manner to the conductor track structure arranged on the substrate 7. By way of power supplies (not shown) to the outside, the driver electronics 14 are connected to a grid connector; they then adapt the grid voltage for an operation of the LEDs 8. However, driver electronics, for example a ballast, can also be arranged outside of the luminaire 1, optionally facilitating an even more compact construction. Further, this also may be e.g. advantageous if light should be emitted to both sides of the substrate 7 (both into the space and towards the wall/ceiling) by means of the luminaire 1.

Below, the production of the illumination apparatus 2 according to the present disclosure is explained in more detail on the basis of FIGS. 2A-2F.

In a first step (FIG. 2A), a copper layer 21 is applied to the substrate 7, to be precise in electroless fashion in a bath. Alternatively, use also could be made e.g. of a substrate with a copper layer that has been laminated, i.e. adhesively bonded, thereon. Then, the conductor track structure 22 is worked out of the copper layer 21 (FIG. 2B), for the purposes of which the copper layer 21 is masked by a photoresist. The latter is exposed and locally opened such that, in a subsequent etching process, the regions that then lie between the conductor tracks 22 are exposed. Thus, the conductor track structure 22 remains after etching (and the photoresist is removed).

Then, the LED 8 is assembled on the conductor track structure 22 in a next step (FIG. 2C), to be precise as a so-called SMD (surface mounted device) component. Thus, the LED 8 has two rear side contacts (not depicted) that face the conductor track structure 22 and the substrate 7 lying therebelow and that are connected to the conductor track structure 22 by way of respectively one integrally bonded joining connection layer, either via an electrically conductive adhesive (e.g. filled with silver) or a low-temperature solder.

Next, a separating joint 23 is structured for each portion 7a, said separating joint separating the respective portion 7a in part from the remaining substrate 7b and said separating joint extending as a non-closed, U-shaped curve (FIG. 2D). However, every one of the portions 7a remains connected to the remaining substrate 7b via a bridge region 24. The separating joints 23 are introduced either by laser cutting, which permits high flexibility, or by punching, which may facilitate a good throughput.

The portions 7a are in each case subsequently folded out of the remaining substrate 7b about the bridge region 24 as a hinge, to be precise by an angle of approximately 45° in each case. Then, a folding line thus respectively extends in the bridge regions 24, said folding line marking the transition between the portion 7a and remaining substrate 7b.

In a last step, the reflector 12 is put together with the substrate 7, for the purposes of which the front side 9 of the substrate 7 is coated with an adhesive film in the region of the remaining substrate 7b, and the substrate 7 and the reflector 12 are then brought against one another. The rear side 10 of the substrate 7 additionally can be, or have been, provided with a reflective layer (not depicted). However, the substrate 7 can already be reflective on account of reflection particles that have been embedded into the PET material.

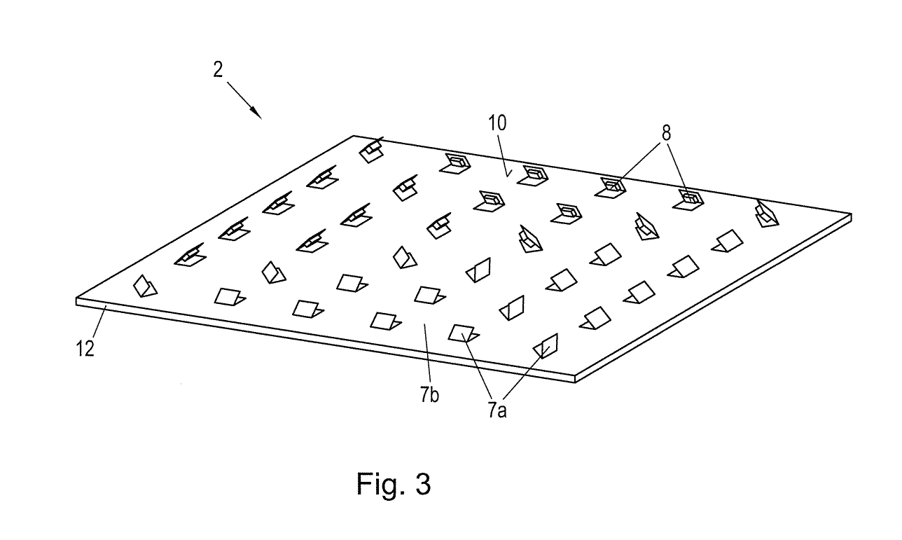

FIG. 3 shows the illumination apparatus 2 in an oblique view, to be precise looking thereon from that rear space into which the portions 7a have been folded. The portions 7a are, of course, respectively folded out toward a rear side 10 of the substrate; this rear side 10 faces the aforementioned rear space, into which the illumination apparatus then also emits the light.

On the basis of two schematic diagrams, FIG. 4 illustrates how the light from the illumination apparatus 2 according to the present disclosure with obliquely placed portions already illuminates a comparatively large region of the diffuser 4 on account of multiple reflections per LED 8. These regions that are respectively illuminated over a large area overlap which, as a result, yields a comparatively good homogeneity of the illuminance on the input side.

For comparison purposes, FIG. 4B shows an arrangement (not according to the present disclosure), in which the LEDs 8 are arranged on a substrate without portions and in each case directly illuminate the diffuser 4. The main propagation direction 11 of the light respectively emitted by one of the LEDs 8 is perpendicular to the input side 5 of the diffuser 4 in this case. The region of the diffuser 4 illuminated by each LED 8 is significantly smaller than in the case of FIG. 4A. Accordingly, the diffuser 4 must be provided with stronger scattering and/or a greater distance must be provided between the LEDs 8 and the diffuser in order to obtain the same illuminance distribution on the output side 6 of the diffuser 4 as in the case of FIG. 4A. Said larger distance is disadvantageous in view of a compact construction; the increased scattering reduces the efficiency.

While the disclosed embodiments have been particularly shown and described with reference to specific embodiments, it should be understood by those skilled in the art that various changes in form and detail may be made therein without departing from the spirit and scope of the disclosed embodiments as defined by the appended claims. The scope of the disclosed embodiments is thus indicated by the appended claims and all changes which come within the meaning and range of equivalency of the claims are therefore intended to be embraced.

1. An illumination apparatus for emitting light, comprising
a planar substrate,
a conductor track structure on the substrate,
a plurality of LEDs that are assembled on the substrate and connected to the conductor track structure in an electrically conductive manner,
wherein a plurality of portions of the substrate are partly separated from the remaining substrate by, in each case, a separating joint that passes through the substrate in the thickness direction of the latter but is open in the direction of longitudinal extent of the latter, i.e. said portions are still respectively connected to the remaining substrate via a bridge region,
said separating joints extending completely within the substrate, in each case at a distance from an edge of the substrate in relation to the surface directions thereof,
with at least one of the LEDs respectively being assembled in said portions and said portions further being folded out of the remaining substrate, in each case about the bridge region, and thus being placed at an angle thereto.

2. The illumination apparatus as claimed in claim 1, wherein the remaining substrate on the substrate makes up at least 30% by area and the remaining substrate is planar, at least where the portions are arranged.

3. The illumination apparatus as claimed in claim 1, wherein the substrate is provided from a plastics material.

4. The illumination apparatus as claimed in claim 1, comprising a carrier on the substrate, said carrier adjoining the substrate in the thickness direction, wherein the carrier has a greater flexural rigidity than the substrate.

5. The illumination apparatus as claimed in claim 1, comprising a planar reflector on the substrate, said planar reflector adjoining the substrate in the thickness direction, wherein the reflector is taken from a material with a reflectance of at least 60%.

6. The illumination apparatus as claimed in claim 4, wherein the illumination apparatus comprises a planar reflector on the substrate, said planar reflector adjoining the substrate in the thickness direction, wherein the reflector is taken from a material with a reflectance of at least 60%, and wherein the carrier is the reflector at the same time.

7. The illumination apparatus as claimed in claim 1, wherein the portions are folded out toward a rear side of the substrate, said rear side being opposite a front side of the substrate on which the LEDs are assembled.

8. The illumination apparatus as claimed in claim 17, wherein the reflector is arranged on the front side of the substrate and said reflector extends, preferably without interruptions, over interruptions in the remaining substrate that are caused by the folded-out portions.

9. The illumination apparatus as claimed in claim 1, wherein the portions are folded out toward a front side of the substrate, the LEDs being assembled on said front side.

10. The illumination apparatus as claimed in claim 1, wherein the substrate has a thickness of at least 150 μm and at most 500 μm and the conductor track structure has a thickness of at least 20 μm and at most 100 μm.

11. A luminaire comprising an illumination apparatus as claimed in claim 1 and a diffuser which is arranged relative to the illumination apparatus in such a way that at least some of the light emitted by the illumination apparatus passes through the diffuser.

12. A method for producing an illumination apparatus as claimed in claim 1, said method comprising the steps:
providing the substrate;
introducing the separating joints;
folding the portions out of the remaining substrate.

13. The method as claimed in claim 12, wherein the separating joints are introduced using a mechanical cutting tool, in particular a punching tool, or by laser cutting.

14. The method as claimed in claim 12, wherein the conductor track structure is plastically deformed locally when folding out the portions.

15. The method as claimed in claim 12, in which the LEDs are already assembled on the substrate when the portions are folded out.

16. The method for producing an illumination apparatus as claimed in claim 4 said method comprising the steps:
providing the substrate;
introducing the separating joints;
folding the portions out of the remaining substrate,
wherein the substrate is arranged on the carrier and/or the reflector after folding out the portions.

17. The illumination apparatus as claimed in claim 5, wherein the portions are folded out toward a rear side of the substrate, said rear side being opposite a front side of the substrate on which the LEDs are assembled.

18. The illumination apparatus as claimed in claim 6, wherein the portions are folded out toward a rear side of the substrate, said rear side being opposite a front side of the substrate on which the LEDs are assembled.

19. The method for producing an illumination apparatus as claimed in claim 5, said method comprising the steps:
providing the substrate;
introducing the separating joints;
folding the portions out of the remaining substrate,
wherein the substrate is arranged on the reflector after folding out the portions.

20. A method for producing a luminaire as claimed in claim 11, said method comprising the steps:
providing the substrate;
introducing the separating joints;
folding the portions out of the remaining substrate.
